(19) United States
(12) Patent Application Publication
(10) Pub. No.: US 2006/0186874 A1
(43) Pub. Date: Aug. 24, 2006

(54) System and method for mechanical testing of freestanding microscale to nanoscale thin films

(75) Inventors: Thomas J. Mackin, San Luis Obispo, CA (US); Zayd C. Leseman, Urbana, IL (US)

Correspondence Address: Steven P. Fallon;GREER, BURNS & CRAIN, LTD., Suite 2500, 300 South Wacker Drive, Chicago, IL, 60606, US

(73) Assignee: The Board of Trustees of the University of Illinois

(21) Appl. No.: 11/292,958

(22) Filed: Dec. 2, 2005

Related U.S. Application Data
(60) Provisional application No. 60/632,676, filed on Dec. 2, 2004.

(51) Int. Cl. G01R 31/28

(52) U.S. Cl. 324/158.1

(57) ABSTRACT

Method and device for measuring mechanical properties of microscale and nanoscale thin film membranes. A testing system comprises a unitary material load cell, including a substrate, a beam supported to the substrate at its ends and otherwise substantially free from the substrate, a test-probe extending from the substrate and connected to the beam, and a scale to measure movement of the test-probe relative to the substrate. The system further comprises a thin film support, supporting a thin film at its circumference and providing a freestanding thin film, and a positioner to move the unitary material load cell for controlled pushing against the freestanding thin film.

### PRIORITY CLAIM

This application claims priority of U.S. Provisional Patent Application Ser. No. 60/632,676, filed Dec. 2, 2004, under 35 U.S.C. § 119.

### STATEMENT OF GOVERNMENT INTEREST

The present invention was made with Government assistance under NSF Grant Contract Number 02-17469. The Government has certain rights in this invention.

### FIELD OF THE INVENTION

A field of the invention is material testing of microscale and nanoscale films.

### BACKGROUND OF THE INVENTION

As part of technologies such as, but not limited to, microelectronic and microelectromechanical systems (MEMS), nanoelectromechanical systems (NEMS), integrated circuits (IC's), thin film optics, etc., accurate measurement of mechanical properties of thin films are important. For example, thin films experience extrinsic loads due to operational and environmental conditions of the devices, and may fail to maintain mechanical integrity, as observed by cracking, delamination, and void or hillock formation under stresses.

Though testing methods for bulk materials are well established, testing methods for microscale and nanoscale materials are still under development. Accurate prediction of thin film material response requires understanding of the fundamental mechanisms of material deformation and fracture occurrence in the microscale and nanoscale. Material properties typically cannot be extrapolated from their respective bulk values, since material behavior often is not only different in the microscale, but is also significantly affected by fabrication processes, and is very sensitive to the influences of interfaces and adjoining materials. For example, significant challenges include the need for ultra-high resolution load/displacement measurement.

Nanoscale materials also have unique properties that vary with length scale, are strongly affected by the presence of native oxides, and may develop large residual/intrinsic stresses due to deposition/growth techniques. These effects are further compounded when testing composites of nanoscale materials.

Mechanical properties of thin films have been measured in several ways. One approach is to deposit a thin film onto a substrate, load the laminate, and use existing composite theory to extract the film properties. An example of this method is taught in Y.-S. Kang and P. S. Ho, “Thickness dependent mechanical behavior of submicron aluminum films,” Journal of Electronic Materials, vol. 26, no. 7, pp. 805-813, 1997. In Kang et al, an Al thin film (60 nm to 480 nm thick) is deposited onto a polyimide substrate (4 μm thick), and then the laminate is loaded. Others have used nanoindentation processes to measure the properties of the as-deposited, such as the process shown in W. C. Oliver and G. M. Pharr, “An improved technique for determining hardness and elastic modulus using load and displacement sensing indentation experiments,” Journal of Materials Research, vol. 7, no. 6, pp. 1564-1583, 1992. In either case, however, testing of layered thin films is complicated by interactions between the film and substrate. The only way to alleviate this problem is to test directly the nanoscale film.

There have been many efforts to measure the mechanical properties of freestanding thin films. One such method of measurement includes a uniaxial tensile test (M. A. Haque and M. T. A. Sailf, “Application of MEMS force sensors for in situ mechanical characterization of nano-scale thin films in SEM and TEM,” Sensors and Actuators A, vol. 97-98, pp. 239-245, 2002). However, the thin film samples in this teaching are cofabricated with the testing device, limiting each device to a single use.

Another known method includes bending of a cantilevered beam (T. P. Weihs, S. Hong, J. C. Bravman, and W. D. Nix, “Mechanical deflection of cantilevered microbeams,” Journal of Materials Research, vol. 3, pp. 931-942, September-October 1998). In this method, a nano-indenter is used to deflect cantilever beams of different materials with dimensions>0.8 μm. This was performed using a custom nano-indenter with a resolution of 0.25 μN load resolution, while the resolution of the current best production nano-indenter is believed to be 50 nN.

Yet another known test is the bulge test (e.g., M. K. Small and W. D. Nix, “Analysis of the accuracy of the bulge test in determining the mechanical properties of thin films,” Journal of Materials Research, vol. 7, pp. 1553-1563, 1990). Though the bulge test is attractive in many respects, it requires pressurized testing of nearly defect-free films (i.e., without pinholes or porosity). As such, the bulge test is not feasible for many material systems, notable polymers and porous low-k dielectrics.

### SUMMARY OF THE INVENTION

The present invention provides a method and apparatus for testing of a freestanding thin-film specimen by measuring its indentation through the response of a microscale load cell. The load cell has a well-determined mechanical response to pushing of a probe tip that extends from the load cell. A testing system comprises a unitary material load cell that includes a substrate, a beam supported to the substrate at its ends and otherwise substantially free from the substrate, a test-probe extending from the substrate and connected to the beam, and a scale to measure movement of the test-probe relative to the substrate. The system further comprises a thin film support that supports a thin film at its circumference and provides a freestanding thin film, and a positioner, preferably capable of sub-nanometer resolution, to move the unitary material load cell for controlled pushing against the freestanding thin film.

### BRIEF DESCRIPTION OF THE DRAWINGS

FIG. 1 is a general schematic of a microscale to nanoscale testing system, according to embodiments of the present invention;

FIGS. 2A-2B are schematic representations of membrane testing systems, shown before and after test film displacement, respectively;

FIG. 3 is a scanning electron microscope (SEM) image of an as-fabricated load cell;

FIGS. 4A-4H show steps in an exemplary process for fabricating a load cell;

FIG. 5 is an optical image of a 300 μm sapphire sphere glued to the bottom of a test-probe tip;

FIGS. 6A-6D show steps in an exemplary process for fabricating a freestanding thin film membrane;

FIG. 7 is an SEM image of a freestanding gold film on a silicon substrate;

FIG. 8 is an optical micrograph showing a probe tip over a freestanding gold film;

FIGS. 9A-9B are schematics of an experimental setup showing a load cell with a spherical testing tip before and after loading a freestanding thin film membrane, respectively;

FIG. 10 is a plot showing the force applied to a freestanding Au circular membrane versus its center deflection for a single fixed-fixed beam;

FIG. 11 is a schematic diagram of an exemplary testing system;

FIG. 12 is a plot showing membrane displacement versus applied load for exemplary experiments performed according to embodiments of the present invention;

FIG. 13 is an optical micrograph of a membrane after loading, showing a dimple approximately 50 μm below center;

FIGS. 14A-14B are optical interferograms of an exemplary experiment, showing a full view of a thin film membrane and an enlarged partial view, respectively;

FIGS. 15A-15D show steps in an exemplary process for fabricating a MEMS-based load cell;

FIG. 16 is an SEM image of a MEMS-based load cell;

FIGS. 17A-17B are schematic diagrams illustrating an experimental load cell calibration setup for direct calibration of force, before and after hanging of a calibrated weight, respectively;

FIG. 18 is a schematic diagram of an experimental load cell calibration system;

FIG. 19 is an optical micrograph of a 500 μm diameter sphere attached to the tip of a load cell by secondary forces;

FIG. 20 is an optical micrograph of a 1000 μm diameter ball lens epoxied to the tip of a load cell;

FIG. 21 is a calibration curve for the load cell shown in FIG. 20, according to exemplary calibration experiments;

FIG. 22 is a schematic diagram of a centrally-loaded fixed-fixed beam developing an axial tensile force due to the beam's elongation;

FIGS. 23A-23B are schematic diagrams of an experimental membrane testing setup, shown before and after loading of a freestanding thin film membrane, respectively;

FIG. 24 is a schematic diagram of a full experimental setup for testing a freestanding thin film membrane; and

FIG. 25 is a plot of data from an experiment showing membrane displacement versus applied load for a single fixed-fixed beam.

### DETAILED DESCRIPTION

Embodiments of the present invention provide a method and apparatus for the displacement testing of a freestanding thin-film specimen. The invention is particularly useful for probing microscale or nanoscale material behavior, where the deformation characteristics are expected to deviate significantly from associated bulk values.

A model for the axisymmetric deflection of a membrane with a finite contact area is described in M. R. Begley and T. J. Mackin, “Spherical indentation of freestanding circular thin films in the membrane regime,” The Journal of Mechanics and Physics of Solids. This model presents closed-form solutions to the problem of finite diameter contact for a centrally deflected circular thin membrane. The resulting closed form solutions were experimentally verified using a nano-indenter on thick, >100 μm films. Experiments of this type are tolerant of materials with defects, and with the addition of a highly sensitive, reusable, MEMS load cell are more precise than the nano-indenter.

A testing device in accordance with exemplary embodiments of the invention is a microscale device that can provide measurements used to test nanoscale samples of material. The device includes a microfabricated unitary material load cell having a test-probe protruding from the midpoint of a fixed-fixed beam. Preferred beams are fabricated from Single-Crystal Silicon (SCS) using standard microfabrication processes. The test-probe includes a probe tip that is precisely controlled (e.g., at sub-nanometer resolution) to push into the center of a freestanding film of material, and the microscale device permits precise determination of the deflection of the freestanding film.

The freestanding thin film material is supported at its circumference in a fashion resembling a drumhead, fixed at the boundaries, to define a circular thin membrane film. A probe tip is aligned precisely to push on the center of the film, preferably using a calibrated piezoelectric stage.

The force and displacement of the thin film are measured, and the mechanical properties of the film may be determined. Preferably, a vernier scale co-fabricated with the load cell measures deflection of the load cell, and the difference between the piezoelectric stage movement and the vernier scale measurement provides a measure of the membrane deflection. Precise control over the beam dimensions and knowledge of the SCS's orientation allows one to accurately determine the load applied to the circular thin membrane film.

Some example properties that may be determined include (but are not limited to) the elastic modulus, the yield strength, and the ultimate strength of the membrane material. The inventors believe that preferred embodiment devices can measure forces at least an order of magnitude less than some known processes, such as a nano-indentor.

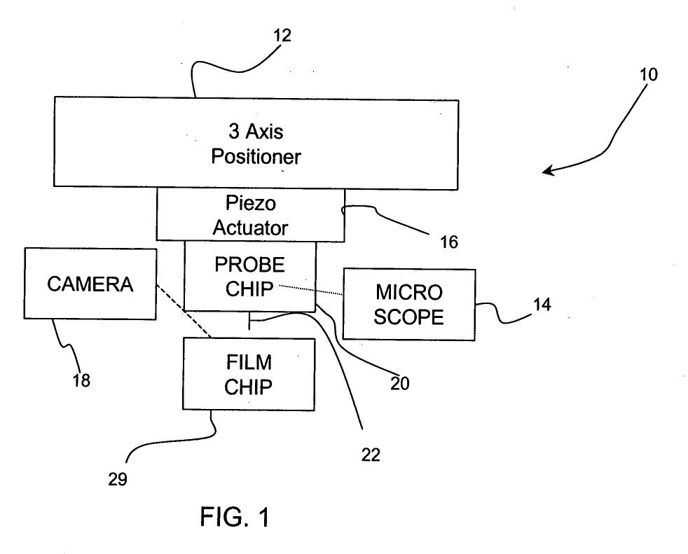

Exemplary embodiments, prototypes, and experimental results will now be discussed, while artisans will appreciate broader aspects of the invention and variations of the same from the following description. Referring to FIG. 1, shown is an exemplary freestanding thin film testing system 10. This system includes a 3-axis micropositioning stage 12, an optical microscope 14, a piezoelectric actuator 16 for subnanometer vertical positioning, and a monitor, such as a CCD camera 18 for recording images of the sample during testing. A camera might also record load cell images and a displacement scale (e.g., a vernier) included thereon.

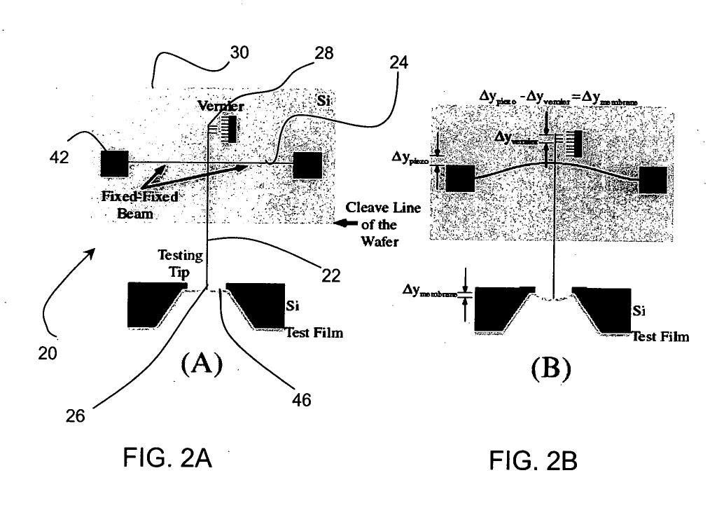

A micro-fabricated load cell, embodied in FIG. 1 as a probe chip 20, is attached to the piezoactuator 16, which, in turn, is attached to the micropositioning stage 12. The load cell 20 is fabricated using standard microfabrication procedures and includes a test-probe 22 attached to a fixed-fixed beam (fixed on two ends but otherwise free-spanning) 24, as shown in FIG. 2. A testing tip 26 is provided at a free end of the test probe, and a vernier 28 is provided at the opposing free end.

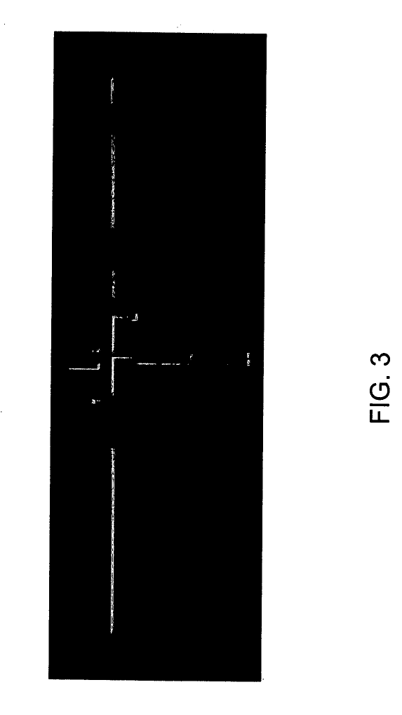

The test-probe 22 extends from the wafer. The structures including the test-probe 22 and the fixed-fixed beam 24 are fabricated on a wafer 30, and following fabrication, the wafer is scored and fractured to allow the testing tip 26 to protrude beyond the edge of the wafer, to contact a freestanding thin film membrane, shown in FIG. 1 as a film chip 29. FIG. 3 shows an SEM image of the testing tip 26 along with a dashed line (cleave line) that shows where the sample would be cleaved.

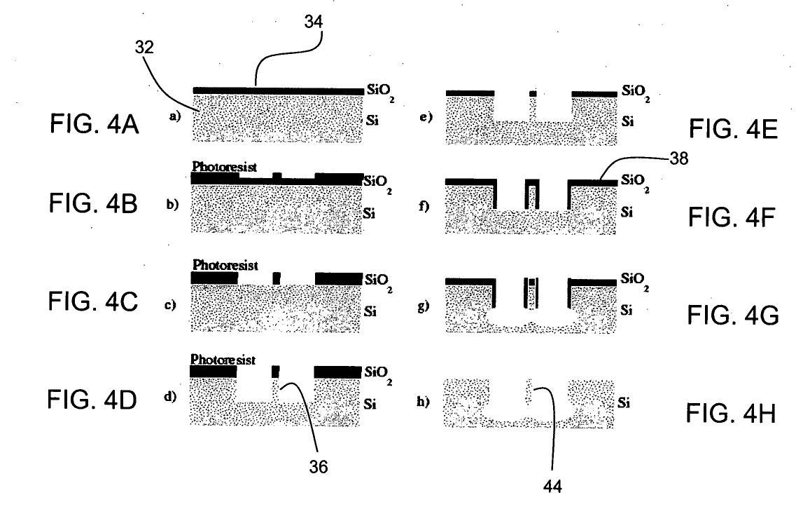

The load cell 20 is fabricated separately from the freestanding thin films. A multi-step process preferably is utilized for fabrication of the load cell. Referring to FIG. 4A, preferred fabrication of the load cell begins with a bare SCS (single crystal silicon) wafer 32 (any crystal orientation). A dielectric masking layer 34 of SiO₂ is grown on the wafer (FIG. 4B). Fixed-fixed beam structures are then patterned into a photoresist layer, followed by anisotropic dry etching of the SiO₂ layer (FIG. 4C).

Next, deep Reactive Ion Etching (DRIE) of Si using the Bosch process (e.g., as described in F. Larmer and A. Schilp, “Method for anisotropically etching silicon”, Patents DE4241045, U.S. Pat. No. 5,501,893, and EP 625285, 1992) is performed (FIG. 4D). The DRIE process creates high-aspect ratio structures 36, as shown in FIGS. 2-3. Remaining photoresist is removed (FIG. 4E).

An additional SiO₂ layer 38 is grown on the structure, and the oxide on the horizontal surfaces is back-etched using an anisotropic dry etch, leaving the vertical sidewalls (FIG. 4F). Isotropic etching (FIG. 4G) then undercuts the Si beams, leaving them freestanding in a fixed-fixed beam structure. The beams are anchored onto the substrate by pads 42 (see FIG. 2) that have widths much greater than the width of the beams, and thus they are not fully undercut. The final microfabrication step is isotropic wet etching of the SiO₂ using HF (FIG. 4H). At this point, a fixed-fixed beam 44 of known dimensions is freestanding above the substrate. The fixed-fixed beam 44 preferably is composed solely of SCS.

The preferred process shown in FIGS. 4A-4H is SCREAM-like, as described, e.g., in Z. L. Zhang and N. C. McDonald, “Fabrication of submicron high-aspect-ratio GaAs actuators,” Journal of Microelecromechanical Structures, vol. 2, pp. 66-73, June 1993, and K. A. Shaw, Z. L. Zhang, and N. C. McDonald, “SCREAM I: a single mask, single-crystal silicon, reactive ion etching process for microelectromechanical structures,” Sensors and Actuators A, vol. 40, pp. 63-70, 1994. However, the process differs in the last step, where instead of metallizing the structure, the dielectric is removed leaving bare Si structures. This change produces a structure made of a homogeneous substance, SCS, whose material properties are well known.

As shown in FIG. 2, the microfabricated load cell includes the SCS fixed-fixed beam 24, the vernier 28 for measuring vertical displacements, the test-probe 22, and a testing tip 26 where vertical pressure will be applied to a freestanding thin film membrane 46. The exemplary fixed-fixed beam 24 in FIG. 2 measures 1500 μm long, 4 μm wide, and 20 μm deep. The length and width are controlled by the dimensions set in the mask, and the depth is set by the DRIE process. Any one of these dimensions can be changed to fine tune the load-deflection behavior to suit the needs of any freestanding circular thin film membrane to be tested. Variations in the fabrication process or alternative processes may be used. However, it is preferred that the process permit fabrication of structures (beam, supports, test-probe) comprised solely of a homogeneous substance, e.g., SCS, whose material properties are well known. This fact combined with the structures' regular and known geometry allows one to calculate the stiffness of the structure with great certainty. Stiffness of exemplary microfabricated load cells may be in the range of 0.108 (μN/μm)-23.4 (μN/μm).

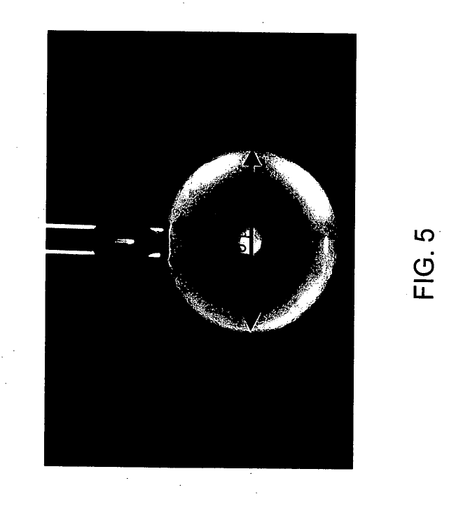

In a final step to completing the load cell, the testing tip 26 is formed on or attached to the free end of the test probe 22. For example, FIG. 5 shows an optical micrograph of a 300 μm diameter sapphire sphere glued to the end of the testing tip. Preferably, the testing tips 26 are terminated by either a Focus Ion Beam (FIB) milled hemispherical tip or an adhered sapphire sphere to provide a known contact radius with the membrane. Dimensions of the test-probe 22 and its related structures are well-controlled during fabrication, which permits the mechanical behavior, for example of the fixed-fixed beam 24 to be known. This permits determination of the thin film response to pushing by the test-probe 22. The 300 μm diameter sapphire sphere, for example, provides a known contact tip radius and facilitates analysis using closed-form membrane solutions.

As shown in FIG. 3, the end of the test-probe 22 preferably has a ladder structure. This structure provides a wick-stop for an epoxy adhesive that may be used, for example, to attach the testing tip 26, such as the ball lens, to the load cell 20.

A multi-stage process is also used for fabrication of the freestanding films. The following illustrates an exemplary process to fabricate freestanding membranes, but other methods are contemplated to perform the fabrication as well.

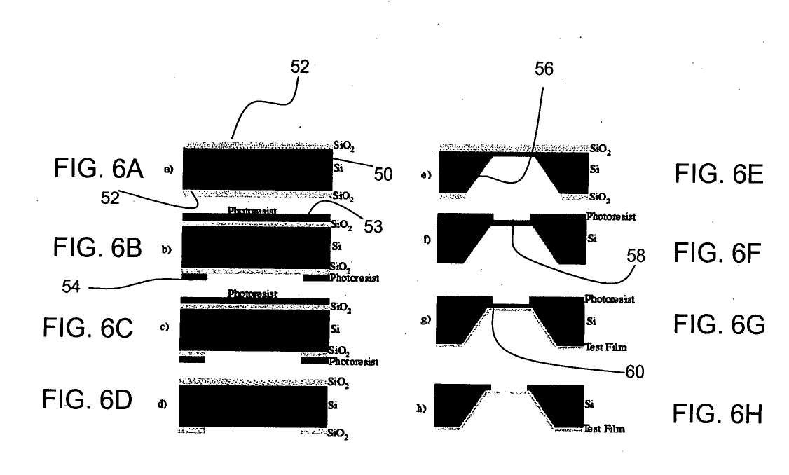

Referring now to FIGS. 6A-6H, fabrication of the exemplary freestanding thin film membrane 29 begins (FIG. 6A) with Si wafers 50 that are p-doped with B, double-side polished, and have a (100) crystal orientation. These (pristine) wafers are then placed into a tube furnace where a wet oxide 52 is grown. Photoresist 53 is formed on the front side and backside of the wafer, and a mask pattern 54 is transferred to the backside of the wafer (FIG. 6B) through standard photolithographic techniques. In an exemplary embodiment, a generic PC-software-printer setup was used to create and print a mask pattern onto a transparency, and the mask pattern was transferred. A preferred mask pattern 54 includes an arrayed pattern of circles defining the areas of the wafer that would be etched through by TMAH, thus leaving an inverted pyramid shape.

The front side of the wafer is also covered in photoresist 53 to protect it from the following fabrication step (FIG. 6C), in which the exposed SiO₂ 52 is removed by submerging the wafer in an HF acid bath, thereby wet etching the film. The photoresist 53 was then removed (FIG. 6D). A TMAH bath is used (e.g., see O. Tabata, R. Asahi, H. Funabashi, K. Shimaoka, and S. Sugiyama, “Anisotropic etching of silicon in TMAH solutions,” Sensors and Actuators A. vol. 34, pp. 51-57, 2002) to anisotropically etch windows 56 from the backside to within ≈50 μm of the top surface (FIG. 6E). The SiO₂ 52 was then removed from the entire wafer, such as by wet HF etch (FIG. 6F).

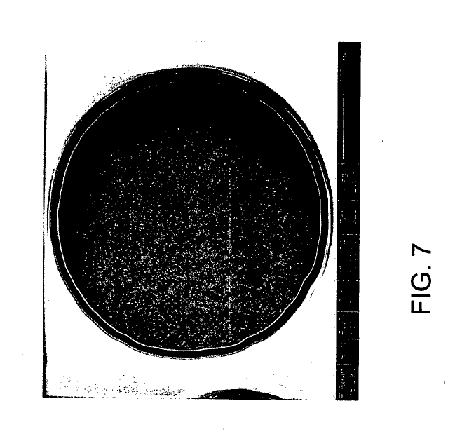

At this point, the top surface of the wafer is patterned with circles 58 of varying diameters that will define the freestanding membrane's diameter. Then, the test film 60 of interest is deposited (FIG. 6G) onto the backside of the sample. Finally, the topside is DRIE using the Bosch Process (FIG. 6H) until all SCS has been removed above the thin film and not below the photoresist. From these steps, the preferred fabrication process yields a freestanding thin film. FIG. 7 shows an SEM micrograph of a freestanding Au film.

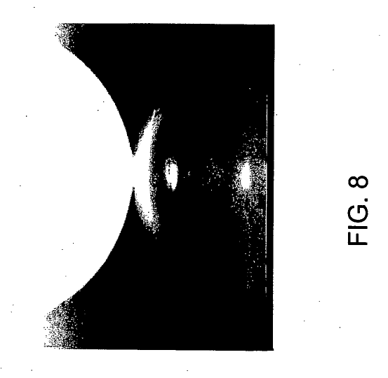

Experiments were conducted with prototypes, and results regarding the prototypes will now be discussed, with respect to the figures, to show example operation. A prototype assembly was mounted vertically on a Physik Instrumente model P-845.60 piezoactuator with displacement resolution of 0.9 nm. The apparatus was clamped onto a 3-axis micropositioning stage and brought into position over a test membrane. The testing tip was aligned over the center of the membrane and moved into near contact with the membrane using the micropositioning stage. The optical microscope was then used to position the testing tip in the center of the test membrane by observing the reflection of the testing tip on the membrane surface, as shown in FIG. 8.

Once within several nanometers, the piezo-actuator was then used to move the testing tip vertically downward. An optical image of the vernier was captured continuously to enable measurement of the testing tip deflection. Membrane displacement can be determined by the difference between the displacement of the piezo-actuator and the vernier. The displacement of the vernier may be converted into load, e.g., using non-linear beam analysis of the fixed-fixed beam.

Generally, the testing tip, which is attached to the load cell, is brought into contact with the center of the freestanding membrane, deflecting it. The deflection of the membrane is related to the motion of the piezo-actuator and the deflection of the load-cell through:
Δy_{membrane}=Δy_{piezo}−Δyᵥₑᵣₙᵢₑᵣ

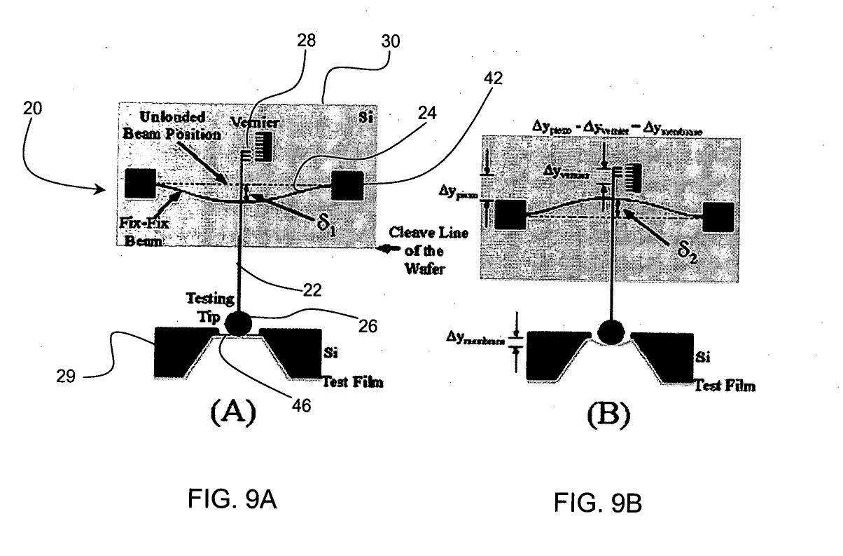

A schematic illustrating this relationship is shown in FIGS. 9A-9B, in which FIG. 9A illustrates an experimental setup before loading of the freestanding thin film membrane, and FIG. 9B illustrates the experiment after loading of the freestanding thin film membrane.

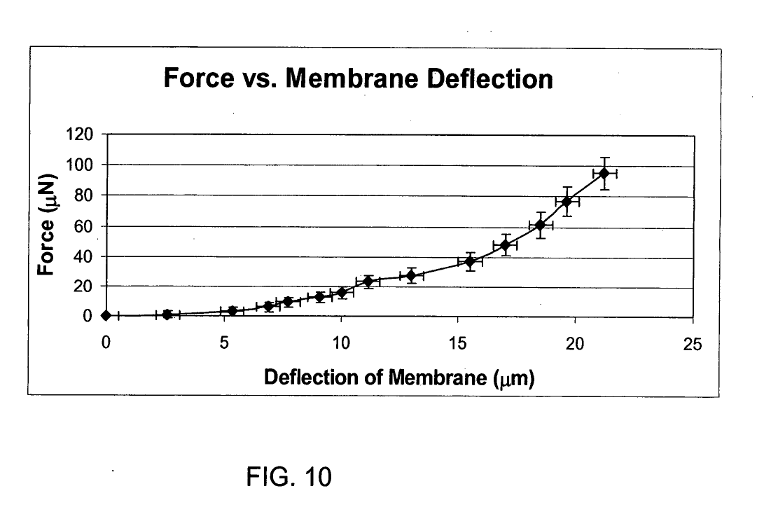

FIG. 10 is a plot of the force applied to a freestanding gold membrane versus the membrane center's displacement for a single fixed-fixed beam, as determined by an exemplary method (to glean mechanical properties of the film the y-axis should be multiplied by two). The fixed-fixed beam used in the experiment was 500 microns long, ˜4.2 microns wide, and ˜14.5 microns deep. Due to the orientation of the Si wafer used to fabricate the device, the loading direction of the beam was along the (110) direction giving a modulus of elasticity of ˜170 GPa. This value was the only assumed value for calculation of the force that was applied to the freestanding thin film membrane. Force was calculated by converting the centerline displacement of the fixed-fixed beam (read off its vernier) by beam theory. The freestanding thin film membrane used in this experiment was ˜865 microns in diameter and ˜445 nm thick. The Au was sputtered onto a (100) Si wafer. Displacement of the membrane was found by subtracting the displacement of the fixed-fixed beam's centerline from the piezo's displacement.

Results clearly show a cubic relation between the force and displacement. This is consistent with the theory described by Begley and Mackin, “Spherical indentation of freestanding circular thin films in the membrane regime,” The Journal of Mechanics and Physics of Solids.

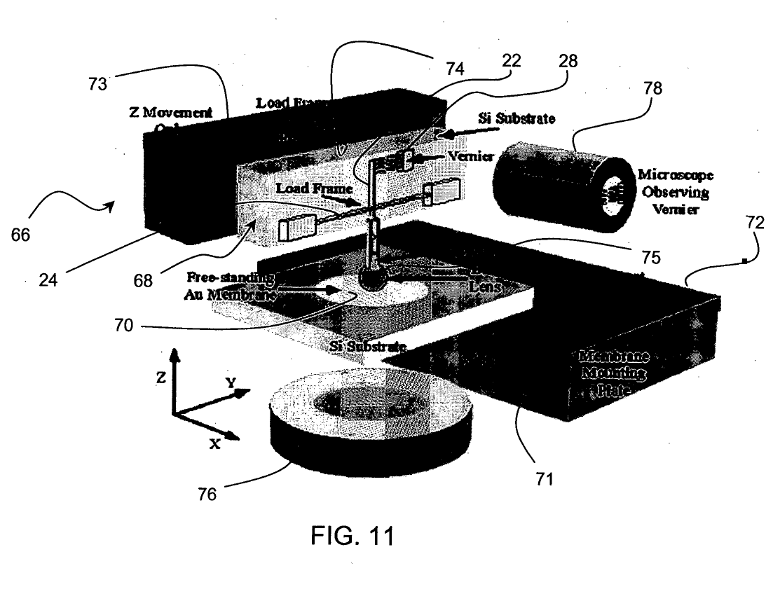

Referring now to FIG. 11, an experimental setup 66 includes four main components: a load cell (shown as a load frame) 68, a freestanding circular thin film membrane 70, high precision translation stages 71, 72, 73, 74, and two microscopes 76, 78. The purposes of the load cell 68 and thin film membrane 70 have already been described. The high resolution stages 71, 72, 73, 74 are used to move the freestanding circular membrane 70 and the load cell 68 into alignment. The two microscopes 76, 78 are used to simultaneously take displacement data from the membrane 70 and from the load cell 68.

In this experimental system, four high resolution stages are used to align the load cell to the center of the membrane. Two stages 71, 72 are utilized to position the center of the freestanding membrane in x-y space under a sphere (ball lens) 75 of the test probe. The other two stages 73, 74 are used to move the ball lens into contact and further deflect the freestanding thin film circular membrane 70. One of these two stages 73 is a manually operated stage that allows for coarse movement of the load cell to near contact with the freestanding circular membrane 70. The other stage 74, a fine movement stage, is mounted on the coarse stage 73. This stage 74 is actuated by a piezoelectric crystal and has displacement control to sub-nanometer resolution. Thus, the limiting factor for the measurement of the deflection of the membrane and load frame is governed by the interferometric measurements made on the membrane 70 and by the vernier 28, respectively.

The two microscopes used in this exemplary setup were an interferometric microscope 76 and an optical microscope 78. The interferometric microscope 76 was positioned below the membrane 70 to measure directly the deflection of the membrane. Deflection of the membrane 70 was measured by counting the number of fringes obtained by the interferometric objective. The optical microscope 78 was positioned in front of the vernier 28 to measure the motion of the load cell 68 via the vernier. As an example, motions of +/−500 nm can be resolved by the vernier. The displacement of the vernier 28 also provides the force applied to the membrane 70.

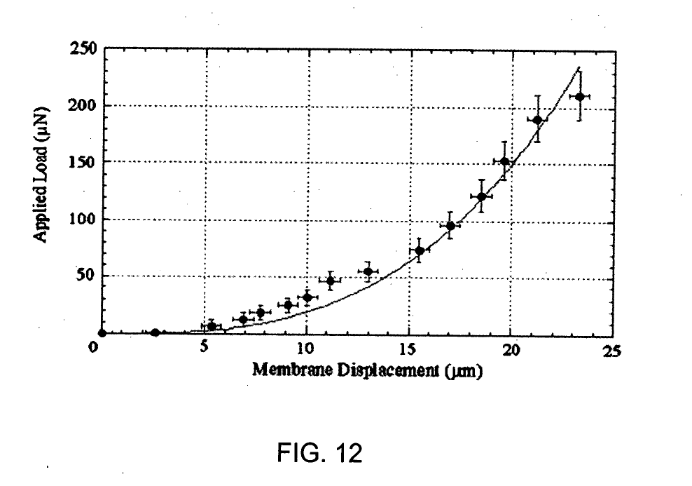

Preliminary experiments were performed using this exemplary setup. Tests were conducted on gold membranes 445 nm thick and 865 μm in diameter. Results of these tests are shown in FIG. 12. Data was collected by watching the vernier 28 located on the centerpoint of the fixed-fixed beam 24 and simultaneously recording the position of the piezoactuator 74. Using the displacement equation provided above, the deflection of the membrane 70 was found. The force applied to the membrane 70 was found using non-linear beam theory, such as described in R. Frisch-Fay, Flexible Bars, Butterworths, 1962.

The x-error bars are associated with the resolution of the vernier 28 (+/−500 nm). Similarly, the y-error bars are related to the vernier's ability to measure the centerpoint deflection of the beam 24, thus contributing to error in force measurement. The line shown in FIG. 12 is a cubic curve fit, as predicted for a membrane with no pre-strain. Particularly, the line is a least squares fit: P=mδ³, where P is the applied load, m is a fitting constant (enveloping constants, geometry, and material properties), and δ is the membrane's displacement.

Though these data do indeed match the theoretically predicted cubic behavior, these experiments are deemed useful only for validation of the experimental procedure. This is due to two misalignments of the experimental apparatus.

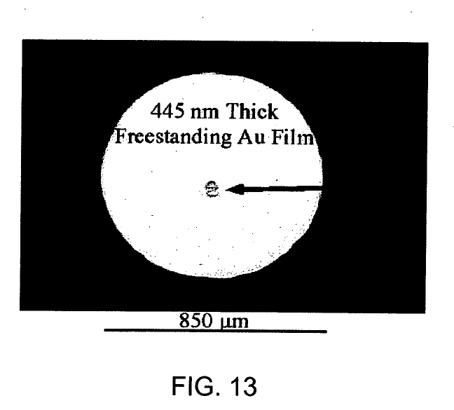

The first misalignment was that of the ball lens to the freestanding circular membrane. FIG. 13, for example, shows plastic deformation due to the ball lens' pressure on the membrane 70. Its location shows, however, that the ball lens 75 was not, in fact, on the center of the membrane 70. The second misalignment is between the end of the load cell 68 and the ball lens 75. From the front, the ball lens appears to be nearly center, as shown in FIG. 13. However, upon inspection from the side (not shown), it was observed that the ball lens 75 is more than 50 μm off center. Thus, a force applied to the bottom of the ball lens 75 will place a torque on the fixed-fixed beam 24 of the load cell 68.

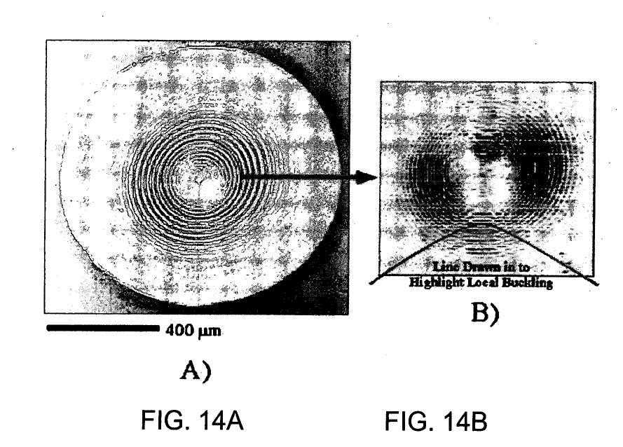

In an alternative experiment using this setup, the interferometric lens 76 was the only microscope that was utilized. It was much easier to align the ball lens 75 to the center of the membrane 70 using this lens. Once proper alignment was achieved, the ball lens 76 was incrementally moved into the membrane. Fringes appeared and radiated from the center of the membrane, as shown in FIG. 14A. FIG. 14A is an optical interferogram showing a full view of the membrane, in which the testing tip (the ball lens 76) is pushing out of the picture from the opposing side of the membrane 70.

Based on the wavelength of the illuminating light, the vertical displacement between any similarly colored fringes is 274 nm. Thus, counting the number of fringes allows one to directly measure the displacement field of the membrane 70 and then calculate the deflection of the load cell through the displacement equation described above.

The interferometric objective enabled observation of the membrane's displacement field and, at higher loads, revealed that the membrane began to buckle, as shown by indicative parabolic shifts in FIG. 14B (a zoomed-in view of the membrane of FIG. 14A). Thus, it is concluded that use of the interferometric objective as well as the optical microscope is preferred to fully monitor the experiment and properly interpret the data.

In certain exemplary embodiments, calibration is incorporated with load testing. Such a setup preferably is multiuse, has a resolution better than 50 nN, is suitable for films with defects, and can operate in liquid environments (e.g., in the case of biopolymers).

An exemplary system uses a load cell based upon MEMS technology. A testing tip is connected to a fixed-fixed beam at its midpoint. Following fabrication, the load cells are calibrated using an approach that allows accurate load measurements during testing of freestanding circular nano-thickness membranes. The fixed-fixed beam with its loading tip is pressed into a circular thin film membrane with a calibrated piezoelectric stage. Deflection of the beam, and thus the load applied to the membrane, is read from a co-fabricated vernier scale, and the displacement field of the membrane is measured from interferometric images of the membrane.

In preferred embodiments, the load cell and freestanding circular nano-thickness thin film membranes were fabricated separately. A combination of vapor phase, wet, and dry etching were used to fabricate the load cell. Most fabrication steps were performed using standard microfabrication equipment. However, due to possible issues with stiction failure, a separate, custom HF vapor etching system was built in exemplary fabrication methods.

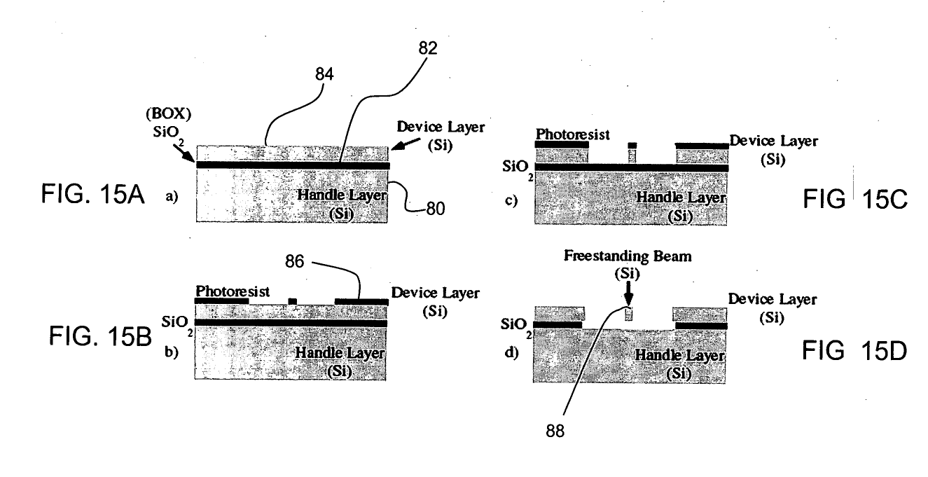

A multi-stage process was utilized to fabricate the load cells. Fabrication began with a substrate having an SOI wafer whose handle layer 80 was 500 μm thick, a 2 μm thick buried oxide (BOX) layer 82, and a 20 μm thick device layer 84 (FIG. 15A). All crystal orientations were (100). Fixed-fixed beams were then patterned (FIG. 15B) using a layer of photoresist 86. The device layer 84 was then etched to the BOX layer 82 by Deep Reactive Ion Etching (DRIE) of Si, using the Bosch process mentioned above (FIG. 15C). This process creates high aspect ratio structures by etching vertically down from the edge of the photoresist layer. Next, the photoresist layer 86 is removed using an O₂ plasma. The beams 88 are then released (FIG. 15D) using either an HF bath or vapor phase HF etch. The HF bath caused almost every structure to be stiction failed to the Si floor, thus a vapor phase etching apparatus was constructed to avoid stiction failure (e.g., see R. Legtenberg, A: C. Tilmans, J. Elders and M. Elwenspoek, “Stiction of surface microstructures after rinsing and drying: Model and investigation of adhesion mechanisms,” Sensors and Actuators, Phys. A, vol. 43, pp. 230-238, 1993; and Y. Fukuta, H. Fujita, and H. Toshiyoski, “Vapor hydrofluoric acid sacrificial release technique for micro electro mechanical systems using labware,” Japanese Journal of Applied Physics, vol. 42, no. 6A, pp. 3690-3694, 2003).

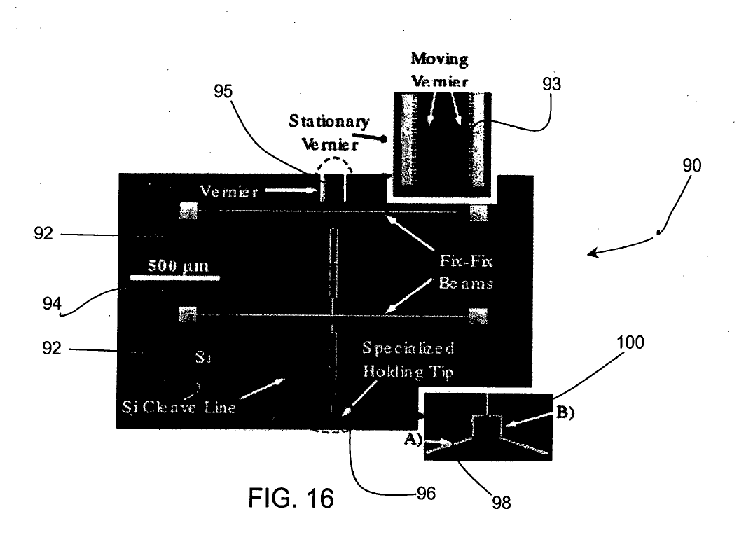

FIG. 16 shows an SEM image of an exemplary MEMS load cell 90 fabricated by using the process shown in FIGS. 15A-15D. The lengths and widths are controlled by the dimensions set in the mask, and the depth of the structure (into the page) is set by the device layer's thickness. Any one of these dimensions can be changed to fine tune the desired stiffness for testing of a particular freestanding nano-thickness membrane. An exemplary stiffness range for devices produced by the present inventors, derived from linear beam theory, is between

$$1.74 \frac{nN}{μ m} to 376 \frac{nN}{μ m} .$$

The load cell 90 shown in FIG. 16 includes two fixed-fixed beams 92 joined at their center by a load transfer structure 94. A double fixed-fixed beam construction is used to counteract any misalignments in the load tip and to limit rotations in and out of the plane of the load cell 90. Also attached at the center of the beams are two other components. The beam located at the top of the device is a moving vernier 93, which moves relative to a stationary vernier 95 for measuring displacements to an uncertainty of 250 nm. The bottom beam is a lampshade-shaped structure 96 used for mounting a spherical load tip to the apparatus. The exemplary tip shown is designed to accommodate a 300 μm diameter sphere. Angled cantilevers 98 of the lampshade-shaped structure 96 make tangent lines to the surface of a 300 μm diameter sphere. Above the angled cantilevers 98 is a wick-stop 100 that allows for a controlled wicking of adhesive or other liquids.

To more accurately measure load, the load cell 90 is calibrated. Other researchers have devised different calibration techniques that make use of buckling beams, strain gauges, resonant frequency of the device, etc. However, one or more of these methods rely on assumptions, due to the unavailability of traceable standards for measurements below 10 nN of force.

The linear relation between force and displacement is F=kx, where F is the force, x is the displacement, and k is the spring constant. Though many methods accurately measure the displacement, x, they assume a spring constant derived from theory. Spring constant, k, is typically a function of the elastic modulus and the dimensions of the spring. These parameters are common sources of variation in flexible mechanisms. Regarding the dimensions of the device, usually researchers assume a constant cross-section. Typically, the assumed cross-section is a rectangle, but most etching processes introduce some degree of taper-creating trapezoidal cross-sections.

Elastic modulus values quoted by most researchers are typically that of bulk, and a range of values for the bulk moduli have been provided. Accordingly, assuming an elastic modulus value and constant dimensions for devices causes subsequent force calculations to inherit error from assumed spring constants. Additionally, the theoretical spring constant's derivation itself may contain assumptions such as: the beam is behaving linearly-elastically; there are only small deflections; the material is isotropic; etc.

MEMS devices are typically fabricated from materials that have been highly processed, thus causing the MEMS′ structural material to have residual stresses. Residual stresses can appear as a result of the mismatch of the coefficients of thermal expansion of materials. Doping changes the chemical makeup of the material. Chemical Machine Polishing (CMP) damages the surface of the materials. These are only a few examples of the processes that can affect the stress state of the structural material for MEMS. These processes have changed the mechanical properties of the material, and thus their mechanical response. Though it is not necessary to quantify the effects of each process and how it affects a device's response, a proper calibration should be performed to see how the material's response has changed overall.

A preferred method for calibration of a MEMS device that requires no assumptions of material properties or dimensions is provided. In a preferred calibration method, a calibrated dead weight hangs from a MEMS load cell. Calibration curves can be determined using measured displacement. Though the method is applicable to nearly any MEMS configuration, the exemplary embodiments described herein calibrate a load cell having the fixed-fixed beam configuration described above. The calibrated force-displacement curve has been compared to the theoretical prediction that predicts a non-linear response of the force-displacement curve.

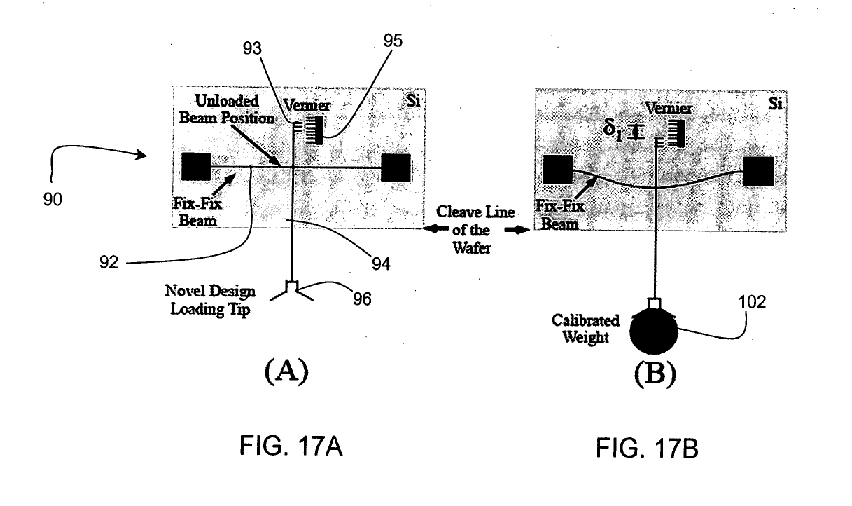

An exemplary calibration of a load cell occurs by hanging calibrated weights 102 (see FIGS. 17A-17B) from the portion of the load cell 90 that extends beyond the cleave line of the wafer. To hang the weights, care was taken during attachment. The weights 102 were properly aligned to the load cell 90 using linear translation stages and goniometers, and they were adhered to the load cell by using secondary forces and adhesives. After hanging of each of the weights 102, the deflection of the fixed-fixed beam 92 is recorded from the beams' vernier 93, as shown in FIGS. 17A and 17B.

Exemplary calibrated weights were commercially available sapphire ball lenses. These were chosen because exemplary load cell experiments used spherical indenters for testing tips. Also, the ball lenses can be manufactured to tight specifications that allow great confidence in the weight of each sphere. An exemplary specification for density, p, is

$$3.98 \pm 0.01 \frac{g}{{cm}^{3}} .$$

Tolerances on all diameters were ±2.54 μm. Independent verification was performed on several samples, through the use of precision balance, and it was found that all samples fall within the manufacturer's specifications.

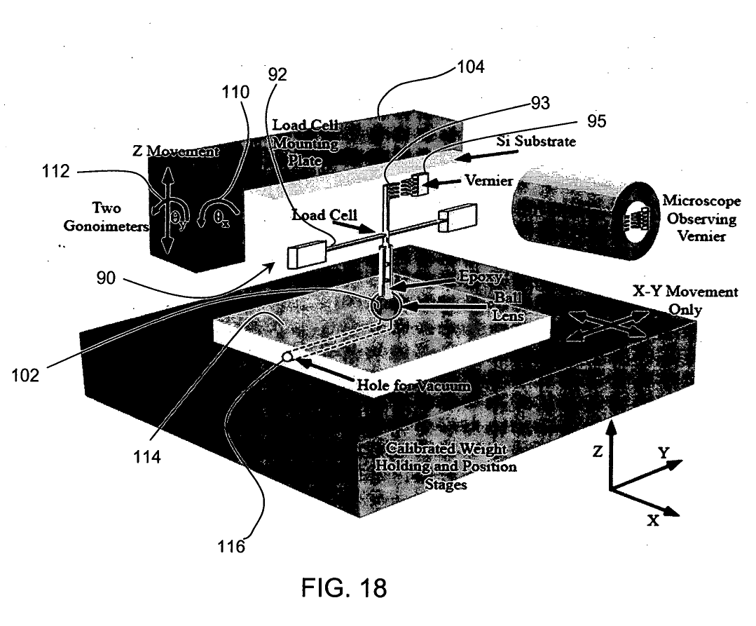

To attain a centrally loaded fixed-fixed beam structure, proper alignment between the load cell 90 and the weights 102 (e.g., ball lenses) is important. Misalignment of weights 102 can cause unwanted torques to arise in the load cell 90. This is accomplished in preferred embodiments through the use of three linear translation stages 104, 106, 108 and two goniometers 110, 112, as shown in FIG. 18. The load cell 90 was mounted onto a fixture 104 that translates in the z-direction with goniometers 110, 112 that allow for rotation around the x- and y-axes. The ball lenses 102 were mounted onto a custom stage 114 that allows for the rigid temporary attachment of the ball lens to the x-y linear translation stages. The ball lenses 102 are rigidly held in place by the application of a vacuum 116 to the underside of the ball lens, thus releasably mounting the ball lens. Upon adhesion of the ball lens 102 to the load cell 90, the vacuum was released. Upon proper alignment of the load cell 90 and ball lens 102 to gravity, the ball lens was adhered to the load cell. The x-axis and y-axis positional stages 106, 108 position the stage 114 into alignment with the load cell 90.

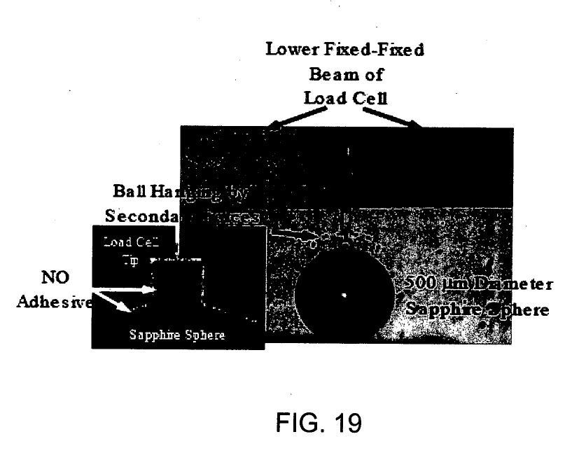

It was anticipated that the fixed-fixed beams 92 would exhibit a nonlinear stiffness in the range of displacements necessary for testing of circular freestanding nano-thickness thin films. Thus, a range of weights was hung from each load cell 90 to capture the load cell's non-linear behavior, and cover the anticipated range of force-displacement responses. For balls measuring 300 and 500 μm in diameter, it was possible, when the humidity was low, to attach the balls using static electricity. When the humidity was high, it was possible to attach the balls using water menisci. FIG. 19 shows an optical micrograph of a 500 μm sapphire ball lens attached by secondary forces to the lampshade-shaped structure. Images of spheres attached by static electricity are similar. Detachment of these smaller spheres was possible through the use of surface tension. A droplet of water was placed onto a substrate and the sphere was brought near. When the sphere was placed into contact with the water, the water quickly pulled the ball from the device.

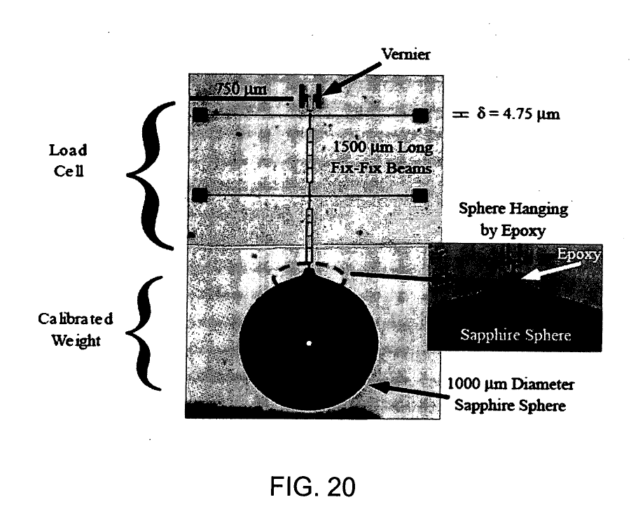

To attach larger size ball lenses, an adhesive was used. FIG. 20 shows an optical micrograph of a load cell terminated by a 1000 μm diameter sphere. Attachment was achieved by dunking the load cell's tip into a droplet of epoxy. The epoxy wicked into the lampshade-shaped structure at the load cell's tip. It was possible to detach the spheres attached by epoxy by vibrating the load cell. This was done at some risk, though, as some devices were damaged in this process.

In certain embodiments, to address the problem of removing the ball lens after attachment by epoxy, a ball lens may be attached using a positive photoresist. Solvents quickly escape the small volume of resist needed to adhere the ball lens to the load cell, especially under the intense light of the microscope. Removal of the ball lens and the photoresist preferably is performed by placing a dish of acetone under the load cell and ball lens assembly. The acetone vapor quickly weakens the positive photoresist because of the large dose of light it has received from the focused light of the microscope. Submersion of the ball lens and device is not necessary for ball lens removal.

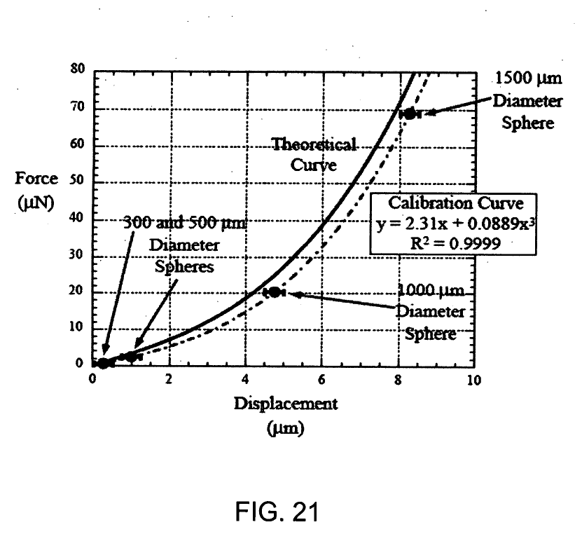

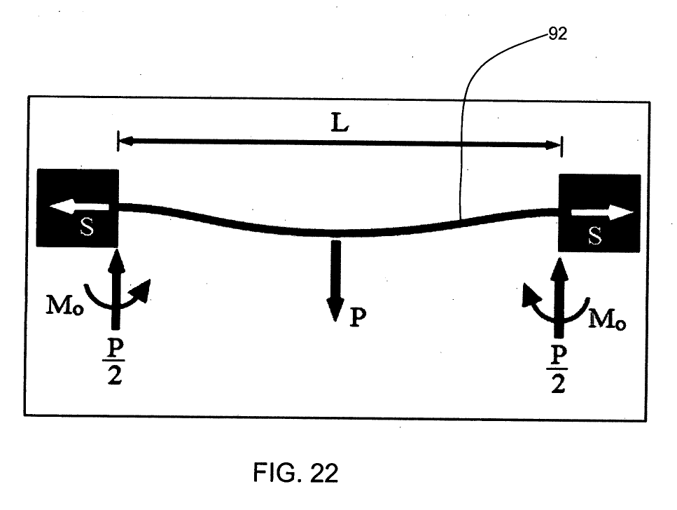

FIG. 21 is a plot of the calibration curve for the load cell shown in FIG. 20. The line to the left is the theoretical force-displacement curve, accounting for the nonlinear stiffening of a centrally loaded fixed-fixed beam. Analyzing the beam, schematically illustrated in FIG. 22, yields the following equations:

$$\begin{matrix}δ = 2 {( \frac{2 I}{{A}_{c}} )}^{\frac{1}{2}} ( u - tanh u ) {( \frac{3}{2} - \frac{1}{2} {tanh}^{2} u - \frac{3}{2} \frac{tanh u}{u} )}^{- \frac{1}{2}} & ( 1 ) \\ P = \frac{2 EI}{{L}^{3}} {( \frac{2 I}{{A}_{c}} )}^{\frac{1}{2}} {{u}^{3} ( \frac{3}{2} - \frac{1}{2} {tanh}^{2} u - \frac{3}{2} \frac{tanh u}{u} )}^{- \frac{1}{2}} \\ where , & ( 2 ) \\ u = \sqrt{\frac{{SL}^{2}}{EI}} & ( 3 )\end{matrix}$$

where δ is the lateral displacement of the midpoint of the fixed-fixed beam 92, I is the moment of inertia, A_{c} is the cross-sectional area of the beam, P is the lateral force applied at the midpoint of the beam, E is the elastic modulus, and L is the length of the beam. Simultaneous solution of equations (1) and (2) are used to plot the theoretical line. To determine this theoretical curve it was necessary to use the SEM and precisely determine the dimensions of the load cell's structure assuming E=170 GPa. Theoretical predictions were quite close to the experimentally observed behavior of the beam. The experimentally measured displacements, for a given weight, are greater than those predicted by the theory. This indicates that the beam is more compliant than predicted, likely due to an axial compressive force on the beam. Beams, cofabricated in the same die, longer than 1500 μm (lengths of 3000 and 5000 μm) were all seen to buckle after release. This indicates a compressive residual stress on the beams. Thus, shorter beams that are not buckled would be expected to be more compliant due to a compressive axial load that is less than the critical buckling force. Both curves were fitted using an equation of the form:
F=k₁x+k₃x³ (4)
where F is the central load on the beams, k₁ is the linear spring constant and k₃ is the cubic spring constant. The R² for the theoretical curve was 1 and for the experimentally measured curve it was 0.9999. Thus, an accurate calibration for this beam is possible only taking into account the cubic spring constant of the beam.

Load cell calibration preferably begins with the smallest sapphire sphere, up to the largest. To simplify the process and to use the full calibration range of the load cell, the heaviest sphere used to calibrate preferably is also the one used to test the freestanding circular membrane.

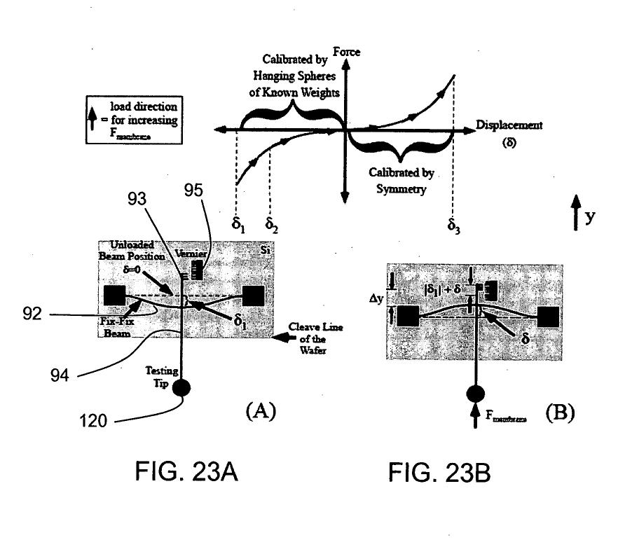

Due to the symmetric nature of the fixed-fixed beam shown in FIG. 16, the calibration range of the device can be doubled. In FIGS. 23A-23B, where FIG. 23A shows an experimental setup before loading of a freestanding thin film membrane 118 using a testing tip 120, and FIG. 23B illustrates the setup after loading, let δ₁ be the deflection of the centerline of a fixed-fixed beam 92 under the weight of the heaviest sphere. If an assumption is made that the beam's response is symmetric, then one can assume that the beam is calibrated from δ₁ to δ₃ and of course |δ₁|=|δ₃|. If a lighter ball were attached to the load cell, then the initial deflection of the fixed-fixed beam might be δ₂. Then, the beam can only have its centerline deflected from δ₂ to δ₃ and be in the calibrated region of the load cell. Thus, having the heaviest weight still hanging from the load cell allows the load cell to be used across the full range of calibration. It will be appreciated that the load cell can be used outside the calibration range, though proper protocol would call for it to be calibrated through the range used.

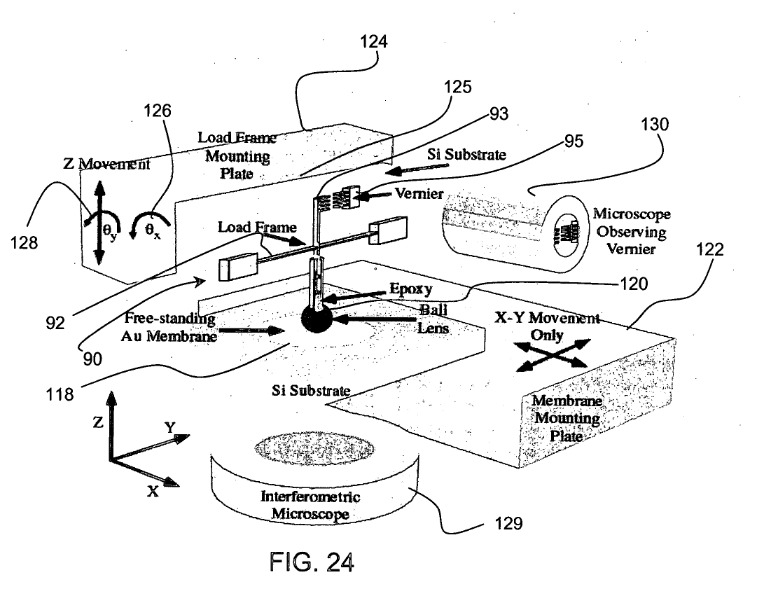

Once the load cells 90 were calibrated, the thin film was tested. Thin film samples were prepared as described above. To perform load testing, the sapphire ball lens 120 was brought into contact with the center of a freestanding membrane 118 (see FIG. 24), deflecting it. In the absence of strain in the load cell's tip, there is a simple relationship between the motion of the piezoelectric cell, the deflection of the fixed-fixed beam's centerpoint, and the centerpoint of the membrane, according to the displacement equation given above.

In an experimental setup, referring to FIG. 24, four main components are used: the load cell 90, the freestanding circular thin membrane 118, high precision linear and rotation stages 122, 124, 125, 126, 128, and two microscopes 129, 130. The high resolution translation stages 122 position the center of the freestanding circular membrane 118 beneath the load cell 120. The two microscopes are used to simultaneously take displacement data from the membrane and from the load cell.

Four high resolution linear stages and two rotation stages are used to completely align and test the membrane with the load cell. Two linear stages (shown together as 122) are utilized to position the center of the freestanding membrane 118 in x-y space under the load cell's tip. The other two linear stages 124, 125 are used to move the ball lens into contact and further deflect the freestanding membrane. One of these two stages is a manually operated stage 124 that allows for coarse movement of the load cell to a position near the freestanding membrane. The other stage, a fine resolution positional stage 125 is mounted on the coarse stage. This stage 125 is actuated by a piezoelectric crystal stack with sub-nanometer resolution. Two goniometers 126, 128 are used to properly align the load cell to the plane of the membrane by rotation about the x-axis and/or y-axis.

The two microscopes used are an interferometric microscope 129 for measuring membrane displacement and an optical microscope 130 to image the vernier. The interferometric microscope 129 was set up below the membrane 118 to record the deflection of the membrane. This deflection was measured by fringe counting. The optical microscope 122 was positioned in front of the vernier 93 to measure the motion of the load cell 90 via the vernier. Motions of +/−250 nm can be resolved by the preferred vernier. As described above, the displacement of the vernier 93 also gives the force applied to the load cell.

Preliminary experiments were performed to validate the functionality of all components. An experiment without the interferometric objective 129 and an experiment with the interferometric objective but without the optical microscope 130 have been performed. In both experiments, a gold membrane approximately 445 nm thick and diameter of 865 μm was used.

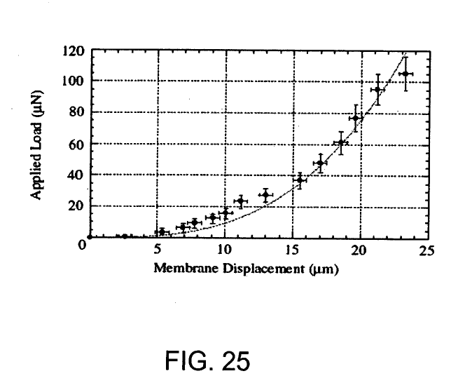

Results for the preliminary experiment are shown in FIG. 25 for a single fixed-fixed beam (to glean mechanical properties of the film the y-axis should be multiplied by two). Data was collected by imaging the vernier located on the centerpoint of the fixed-fixed beam 92 and simultaneously recording the position of the piezoactuator 125. Thus, using the displacement equation, the deflection of the membrane 118 was found. In the first set of experiments the force applied to the membrane was found using non-linear beam theory, not by using a calibrated beam. The x-error bars are associated with the resolution of the vernier. Similarly, the y-error bars are related to the vernier's ability to measure the center point deflection of the beam. The line on FIG. 25 is a cubic curve fit. Analysis was performed in exemplary embodiments using the closed form membrane equation disclosed in Begley and Mackin, “Spherical indentation of freestanding circular thin films in the membrane regime,” The Journal of Mechanics and Physics of Solids:

$$P = \frac{9 π}{16} ( \frac{{EhR}^{\frac{1}{4}}}{{a}^{\frac{9}{4}}} ) {d}^{3} \qquad ( 5 )$$

where P is the central load on the freestanding membrane, h is the film's thickness, R is the radius of the indenter, a is the radius of the film, and d is the membrane deflection (m is the constant used in the least squares fit equation described above).

Though misalignment occurred in preliminary experiments, the problem of misalignment of the sapphire sphere ball lens 120 to the load cell 90 and to the freestanding circular nano-thickness thin film membrane 118 has been addressed by the addition of the two goniometers 126, 128 for proper rotational alignment of the components.

A redundancy exists in the exemplary system. To solve the displacement equation stated above, only two quantities are necessary. The piezoelectric crystal stack and then the interferometer have the highest displacement accuracies. Thus, it appears that the optical microscope 130 observing the vernier 93 on the load cell 90 is unnecessary. However, in preferred embodiments the optical microscope 130 is used to monitor the state of the load cell 90. Misalignments that cause torques to the load cell 90 would likely cause rotations of the vernier 93 into and out of the plane of the load cell. These rotations can be observed at the vernier 93. Also, the displacement readings of the vernier are useful as a crosscheck of the other two measurements.

While various embodiments of the present invention have been shown and described, it should be understood that other modifications, substitutions, and alternatives are apparent to one of ordinary skill in the art. Such modifications, substitutions, and alternatives can be made without departing from the spirit and scope of the invention, which should be determined from the appended claims.

Various features of the invention are set forth in the appended claims.

What is claimed is:

1. A micro-scale and nano-scale chip thin-film testing system comprising:
a unitary material load cell, the load cell including:
a substrate;
a beam supported by the substrate at its ends and otherwise substantially free from the substrate;
a test-probe extending from the substrate perpendicular to said beam and connected to said beam;
a scale to measure movement of the test-probe relative to the substrate;
a thin film support, the support supporting a thin film at its circumeference to define a freestanding thin film; and
a micro-positioner to move said unitary material load cell for controlled pushing against the freestanding thin film.

2. The system of claim 1, wherein said unitary material load cell comprises single crystal silicon (SCS).

3. The system of claim 1, wherein said beam comprises a fixed-fixed beam.

4. The system of claim 1, wherein said test-probe comprises a load-bearing member, and wherein the system further comprises:
a testing tip at a free end of said test-probe.

5. The system of claim 4, wherein said testing tip comprises a ball lens.

6. The system of claim 5, wherein the ball lens comprises a sapphire sphere having a predetermined diameter.

7. The system of claim 5, wherein the free end of said test-probe comprises a plurality of angled cantilevers positioned to make tangential lines with respect to the ball lens when the ball lens is attached to the free end.

8. The system of claim 5, wherein the ball lens is attached to the free end of said test-probe via an adhesive, and wherein the load-bearing member comprises a wick-stop for the adhesive.

9. The system of claim 1, wherein said micro-positioner comprises:
a piezoactuated positioner coupled to said load cell for sub-nanometer resolution controlled movement of said test-probe with respect to said thin film support;
a positioner coupled to said piezoactuated positioner for coarse movement of said piezoactuated positioner.

10. The system of claim 9, wherein said micro-positioner further comprises:
a high resolution positioner coupled to said thin film support for positioning said thin film support with respect to said test-probe.

11. The system of claim 9, wherein said micro-positioner further comprises:
a rotational positioner coupled to said load cell for rotational movement of said load cell with respect to said thin film support.

12. The system of claim 1, further comprising:
an optical microscope positioned to observe said scale.

13. The system of claim 12, further comprising:
at least one of a camera and an interferometric microscope positioned to observe deflection of the freestanding thin film.

14. The system of claim 1, wherein said load cell further comprises:
a fixed-fixed beam disposed in parallel with respect to said beam and connected to said beam via said test probe, wherein said test probe substantially bisects said fixed-fixed beam and said beam.

15. The system of claim 1, wherein said scale comprises:
a stationary vernier scale;
a moving vernier scale disposed at a free end of said test-probe and aligned with said stationary vernier scale, whereby relative movement of said moving vernier scale with respect to said stationary vernier scale can be observed.

16. A method for nano-scale or micro-scale thin film testing, comprising:
supporting a thin film at its circumference to provide a freestanding thin film;
pushing against the freestanding thin film with a micro-scale test-probe at the center of the freestanding thin film, the test-probe being part of a movable load cell having well-defined mechanical properties;
measuring an amount of displacement of the test-probe relative to the load cell; and
determining material properties of the thin film from the amount of displacement measured in said step of measuring.

17. The method of claim 16, wherein said pushing against the freestanding thin film comprises:
actuating a micropositioner to lower the test-probe onto the freestanding thin film.

18. The method of claim 16, wherein said pushing against the freestanding thin film comprises:
aligning the test-probe substantially with a center of the freestanding thin film;
actuating a micropositioner to lower the test-probe onto the freestanding thin film.

19. The method of claim 16, wherein said pushing against the freestanding test film comprises:
pushing against the freestanding thin film with a testing tip disposed at a free end of the test-probe, wherein the testing tip has a known radius.

20. The method of claim 16, wherein the test-probe is coupled to at least one fixed-fixed beam disposed perpendicular to the test-probe, and wherein said pushing against the freestanding thin film deflects the at least one fixed-fixed beam.

21. The method of claim 16, wherein said measuring displacement comprises:
measuring a movement of a moving scale relative to a stationary scale, wherein the moving scale is coupled to a free end of the test-probe opposing an end pushing against the freestanding thin film and the stationary scale is fixedly coupled to the load cell.

22. The method of claim 16, wherein said determining material properties comprises:
measuring a movement of the load cell;
determining a deflection of the freestanding thin film based on said measured movement of the load cell and said measured displacement.

23. The method of claim 22, wherein said pushing against the freestanding test film comprises:
pushing against the freestanding thin film with a testing tip disposed at a free end of the test-probe, wherein the testing tip has a known radius; and
wherein said determining material properties further comprises:
determining a force applied to the freestanding thin film based on an amount of displacement of the measured test-probe;
determining material properties based on the determined membrane deflection, the determined force applied, dimensions of the freestanding thin film, and the radius of the testing tip.

24. The method of claim 23, wherein the freestanding thin film is circular, and further comprising:
aligning the testing tip with a center of the freestanding thin film before said pushing against the thin film.

25. The method of claim 16, further comprising:
observing displacement of the freestanding thin film using an interferometric microscope.

26. The method of claim 16, wherein the load cell comprises:
a substrate;
the test-probe;
at least one fixed-fixed beam disposed perpendicular to the test-probe and fixed to the test-probe, the fixed-fixed beam being fixed to the substrate;
a testing tip disposed at a free end of the test probe;
a moving scale disposed at an opposing free end of the test probe.

27. The method of claim 26, wherein at least the substrate, the test-probe, and the fixed-fixed beam comprise a unitary material.

28. The method of claim 27, wherein the unitary material comprises single crystal silicon (SCS).

29. The method of claim 28, further comprising:
before said pushing, calibrating the load cell.

30. The method of claim 29, wherein said calibrating comprises:
loading the test probe with at least one calibrated weight;
measuring displacement of the test-probe relative to the load cell.

31. A method for calibrating a micro-scale or nano-scale load cell having a probe and a substrate, the method comprising:
providing a load cell having a probe and a substrate;
loading a probe of the load cell at a free end with at least one calibrated weight;
for each calibrated weight, measuring a displacement of an opposing free end of the loaded probe relative to the substrate;
determining a relationship between force and displacement for the load cell based on the measured displacement for each calibrated weight.

32. The method of claim 31, wherein the load cell further comprises a beam supported by the substrate at its ends and otherwise substantially free from the substrate, the beam being connected to the probe, the probe extending perpendicularly with respect to the beam and bisecting the beam.

33. The method of claim 32, wherein said loading a probe comprises mounting the calibrated weight to a tip at the free end of the probe.

34. The method of claim 33, wherein said mounting comprises adhering the calibrated weight to the tip.

35. The method of claim 32, wherein said measuring a displacement comprises determining a movement of a moving scale at the opposing free end with respect to a stationary scale attached to the substrate.

36. The method of claim 32, further comprising:
aligning the calibrated weight with the probe.

37. The method of claim 36, wherein said aligning comprises:
releasably mounting the calibrated weight to a stage;
positioning the probe over the stage to align the probe with the calibrated weight;
adhering the calibrated weight to the positioned probe;
releasing the calibrated weight from the stage.

38. The method of claim 37, wherein said releasably mounting comprises providing a vacuum to hold the calibrated weight onto the stage.

39. The method of claim 31, wherein said loading a probe comprises loading the probe with a series of calibrated weights.

40. The method of claim 39, wherein said determining a relationship comprises:
determining a series of points, each of the series of points relating to force and displacement;
determining a calibrated force-displacement relationship based on the determined series of points.
